(19) United States
(12) Patent Application Publication
(10) Pub. No.: US 2004/0155646 A1
(43) Pub. Date: Aug. 12, 2004

(54) Testing apparatus and method for testing the contacting between a semiconductor device and a carrier

(75) Inventor: Holger Hoppe, Mering (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munich (DE)

(21) Appl. No.: 10/725,938

(22) Filed: Dec. 3, 2003

(30) Foreign Application Priority Data
Dec. 4, 2002 (DE) 10256692.5

(51) Int. Cl. G01R 1/00

(52) U.S. Cl. 324/158.1

(57) ABSTRACT

The invention relates to a testing apparatus, a testing system and a testing method, in particular for testing the contacting between a semiconductor device and a carrier. The invention includes loading of a carrier with a semiconductor device, such that the contacting between the carrier and the semiconductor device is tested immediately after the loading of the carrier with the semiconductor device.

### CLAIM FOR PRIORITY

This application claims the benefit of priority to German Application No. 102 56 692.5, filed in the German language on Dec. 4, 2002, the contents of which are hereby incorporated by reference.

### TECHNICAL FIELD OF THE INVENTION

The invention relates to a testing apparatus, a testing system, and a testing method, in particular a method for testing the contacting between a semiconductor device and a carrier.

### BACKGROUND OF THE INVENTION

Semiconductor devices, e.g. appropriate, integrated (analog or digital) computing circuits, semiconductor memory devices such as functional memory devices (PLAs, PALs, etc.) and table memory devices (e.g. ROMs or RAMs, in particular SRAMs and DRAMs), etc. are subject to comprehensive tests in the course of the manufacturing process.

For the common manufacturing of a plurality of (in general identical) semiconductor devices, a so-called wafer (i.e. a thin disc consisting of monocrystalline silicon) is used.

The wafer is processed appropriately (e.g. subject to a plurality of coating, exposure, etching, diffusion and implantation process steps, etc.), and subsequently sawn apart (or e.g. scratched and broken), so that the individual devices are then available.

During the manufacturing of semiconductor devices (e.g. of DRAMs (Dynamic Random Access Memories or dynamic read-write memories, respectively), in particular of DDR-DRAMs (Double Data Rate—DRAMs), the devices (still available on the wafer) can—after the appropriate above-mentioned processing steps have been performed at the wafer—be subject to corresponding testing methods by means of a testing apparatus at a testing station.

After the sawing apart of the wafer, the devices—which are then available individually—are loaded each individually in so-called carriers (i.e. a corresponding packing) at a carrier loading station (in general in a fully automated manner by means of appropriate loading-/deloading machines or apparatuses).

After a carrier has been loaded with a corresponding device, the respective carrier is, together with other carriers loaded with a corresponding device each, placed on a transport means, e.g. a so-called tray and is, by means of the transport means—again in a fully automated manner—transported further to another testing station.

There (in a fully automated manner, e.g. by means of a further loading-/deloading machine) individual carriers each are inserted into a corresponding adapter or socket, respectively, that is connected with a (further) testing apparatus. Subsequently, the device available in the respective carrier is subject to corresponding (further) testing methods.

The above-mentioned loading of the carrier with a corresponding device at the carrier loading station must be effected at very high precision (in particular at a precision in the μm range). Otherwise, it will not be guaranteed that the pads of the device—which partially have small dimensions only—are safely contacting the corresponding pads of the carrier.

A correspondingly faulty contacting between the carrier and the respective semiconductor device is—with the above-explained proceeding—only detected at the above-mentioned (further) testing station (i.e. only after the carrier has been transported further from the carrier loading station to the (further) testing station, or only during the performance of the above-mentioned (further) testing method, respectively).

One cannot, however, determine then whether a malfunctioning detected in the (further) testing method is to be attributed to a miscontacting between the carrier and the device, or to a miscontacting between the carrier and the adapter or socket, respectively, or to an actual malfunctioning of the device.

### SUMMARY OF THE INVENTION

The invention provides a testing apparatus, a testing system, and a testing method, in particular for testing the contacting between a semiconductor device and a carrier.

In accordance with one embodiment of the invention, a testing method, in particular for testing the contacting between a semiconductor device and a carrier, is provided, wherein the method includes loading of a carrier with a semiconductor device, such that the contacting between the carrier and the semiconductor device is tested immediately after the carrier has been loaded with the semiconductor device.

In one aspect, the testing method additionally includes connecting the carrier to a testing apparatus.

Preferably, the contacting between the carrier and the semiconductor device is then tested by means of the testing apparatus connected to the carrier.

It is preferable that the carrier is first connected to the testing apparatus, and subsequently the carrier is loaded with the semiconductor device (and the above-mentioned contact test is performed immediately thereafter).

In another emobidment of the invention, the carrier is loaded at a carrier loading station, with the contacting between the carrier and the semiconductor device being tested before the carrier is transported further to another station, in particular to a semiconductor device functioning test station.

This avoids—in the case of miscontacting between the carrier and the semiconductor device—the existence of a corresponding fault being detected at the further station, in particular at the semiconductor device functioning test station.

An advantage of the invention is that the contacting between the carrier and the semiconductor device is tested after a relatively short time, in particular less than 2 seconds, or less than 1, 0.5, or 0.1 seconds after the carrier has been loaded with the semiconductor device.

According to a further aspect of the invention, a testing system is provided, including a testing apparatus to which a carrier may be connected, and which is configured such that the testing apparatus tests the contacting between the carrier and the semiconductor device immediately after the carrier has been loaded with a semiconductor device.

Furthermore, in accordance with a third aspect of the invention, a testing apparatus for use in a testing system of this type is provided, with the testing apparatus being configured such that it tests the contacting between the carrier and the semiconductor device immediately after a carrier has been loaded with a semiconductor device.

### BRIEF DESCRIPTION OF THE DRAWINGS

In the following, the invention will be explained in detail by means of an embodiment and the enclosed drawing. The drawing shows:

FIG. 1 shows stations passed through by corresponding semiconductor devices during the manufacturing of semiconductor devices.

FIG. 2 shows the loading station illustrated in FIG. 1, and of the system provided therein, for illustrating the testing performed with the embodiment of the invention.

FIG. 3 shows a flow chart of the method performed during testing in accordance with the embodiment of the invention.

### DETAILED DESCRIPTION OF THE INVENTION

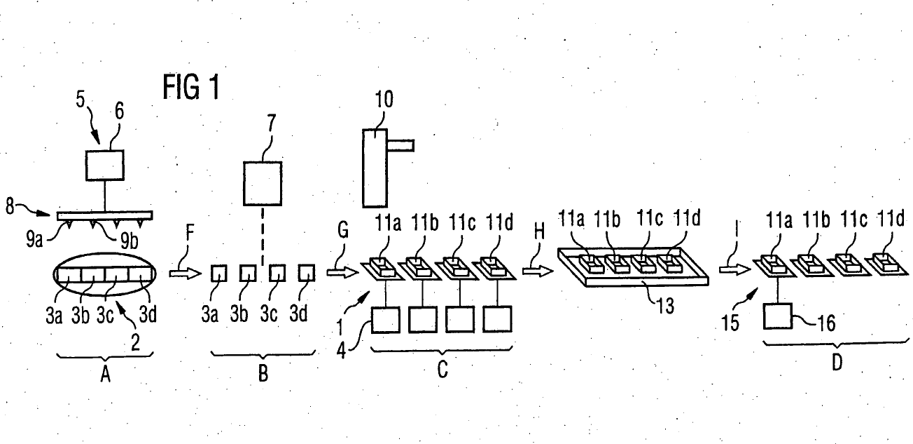

FIG. 1 shows some (of a plurality of further, not illustrated) stations A, B, C, D that are passed through by corresponding semiconductor devices 3a, 3b, 3c, 3d during the manufacturing of semiconductor devices 3a, 3b, 3c, 3d.

At station A, semiconductor devices 3a, 3b, 3c, 3d that are still available on a silicon disc or a wafer 2, respectively, are subject to a testing method by means of a testing system 5.

Before that, the wafer 2 had been subject, at stations not illustrated in FIG. 1 and preceding the stations A, B, C, D, to appropriate, conventional coating, exposure, etching, diffusion and implantation process steps.

The semiconductor devices 3a, 3b, 3c, 3d may, for example, be appropriate, integrated (analog or digital) computing circuits, or semiconductor memory devices such as functional memory devices (PLAs, PALs, etc.) or table memory devices (e.g. ROMs or RAMs), in particular SRAMs and DRAMs (here e.g. DRAMs (Dynamic Random Access Memories or dynamic read-write memories, respectively) with double data rate (DDR-DRAMs=Double Data Rate DRAMs), advantageously High-Speed DDR DRAMs).

The voltages or testing signals, respectively, required at station A for testing the semiconductor devices 3a, 3b, 3c, 3d on the wafer 2 are generated by a testing apparatus 6 and are, by means of a semiconductor device probe card 8 (for example, by means of appropriate contact needles 9a, 9b provided on the probe card 8), applied to corresponding pads of the semiconductor devices 3a, 3b, 3c, 3.

When the testing method(s) has (have) been finished successfully, the wafer 2 is transported further (in a fully automated manner) to the following station B (cf. Arrow F) and is there, by means of an appropriate machine 7, sawn apart (or e.g. scratched and broken), so that the individual semiconductor devices 3a, 3b, 3c, 3d are then available.

Before being sawn apart, the wafer 2 may, in a manner known per se, have been covered with a foil.

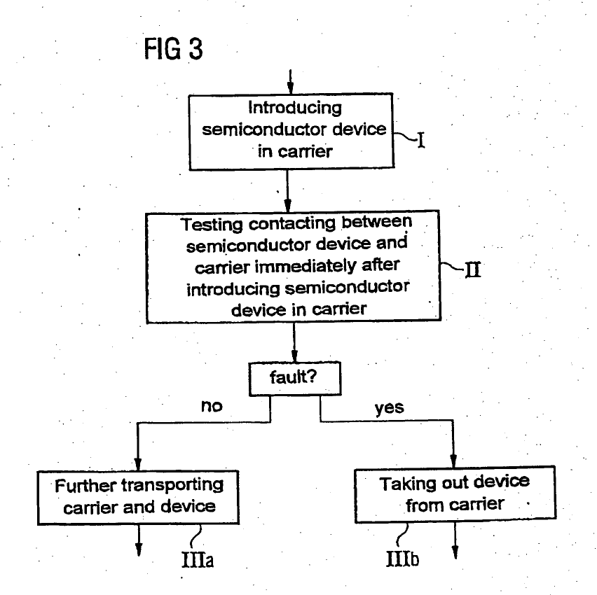

After sawing apart the wafer 2 at station B, the devices 3a, 3b, 3c, 3d are (again in an automated manner, e.g. by means of an appropriate conveying machine) transported further to the following station C (in this case: a carrier loading station C) (e.g. directly (or individually, respectively), or alternatively e.g. by means of an appropriate tray) (cf. Arrow G), and are there—individually each—loaded in an automated manner by means of an appropriate machine 10 (loading or loading-/deloading machine, respectively) in a carrier 11a or a packing 11a, respectively—cf. also step I, FIG. 3—(alternatively, the function of the above-mentioned conveying machine and of the above-mentioned loading machine 10 may, for instance, also be taken over by one single machine).

As further illustrated in FIG. 1, a testing system 1 (or several testing systems of identical structure each) is/are provided at the carrier loading station C, by means of which a specific testing method, which will be explained in detail below, is performed at the carrier loading station C.

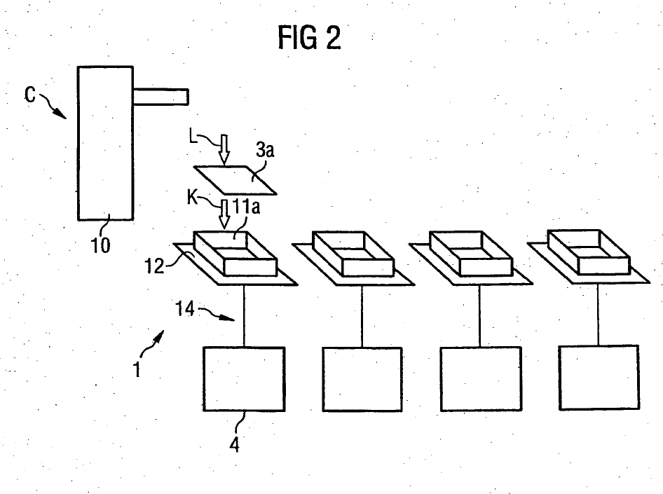

FIG. 2 shows a schematic detail representation of the carrier loading station C.

As illustrated in FIG. 2, at the carrier loading station C the respective carrier 11a is first (in an automated manner, e.g. by means of an appropriate, not illustrated, separate machine (or e.g. the above-mentioned loading or loading-/conveying machine, respectively)) introduced in a carrier socket 12 or carrier adapter 12, respectively, which is connected to a corresponding testing apparatus 4 (cf. Arrow K).

As carrier 11a, a conventional TSOP66 carrier may, for instance be used, and as socket 12 a conventional TSOP66 socket.

By introducing the carrier 11a in the socket 12, it is achieved that testing signals output by the testing apparatus 4 and transferred to the socket 12 e.g. by means of corresponding lines 14 are, via pads of the carrier 11a which are in contact with the respective pads of the socket 12, supplied to the carrier 11a.

When then, next, as is illustrated by an Arrow L (and as was already explained above), the corresponding semiconductor device 3a is (e.g. by means of the above-mentioned loading machine 10) introduced in the carrier 11a (and the carrier 11a is then, in a manner known per se, closed), corresponding semiconductor device contacts (that are, for instance, provided at the bottom of the semiconductor device 3a) get into contact with corresponding contacts at the carrier 11a (that are, for instance, provided at the top of the carrier 11a) (the contacts being connected with the above-mentioned carrier pads contacting the socket pads).

Thus, directly after the introducing of the semiconductor device 3a in the carrier 11a (or directly after the closing of the carrier, respectively) the above-mentioned testing signals output by the testing apparatus 4 can (via the abovementioned lines 14, the socket 12, the carrier 11a, and the semiconductor device contacts contacting the corresponding contacts at the carrier 11a) be transferred to the semiconductor device 3a.

The signals output at the corresponding semiconductor device contacts in reaction to the testing signals input are tapped by corresponding contacts (contacting same) at the carrier 11a and supplied to the testing apparatus 4 via the socket 12 and the lines 14, where an evaluation of the corresponding signals may take place.

The testing apparatus 4 can—directly after the introduction of the semiconductor device 3a in the carrier 11a (or directly after the closing of the carrier 11a, respectively), in particular e.g. in less than 2, 1, 0.5 or 0.1 seconds after the introduction of the semiconductor device 3a or the closing of the carrier 11a, respectively —detect whether contacts provided at the semiconductor device 3a (or semiconductor device contacts used—later on, e.g. at station E—for the actual device functioning test purposes, or a part thereof, and/or specific device contacts explained in detail further below) safely contact the corresponding contacts at the carrier 11a (or whether—e.g. since the device 3a was not exactly introduced in the correct position in the carrier 11a, or e.g. since the device 3a got out of place prior to or during closing of the carrier 11a, etc.—there exists no or not sufficient contact of one or a plurality of the above-mentioned device contacts with the corresponding carrier contact)—cf. also step II, FIG. 3—

This is, for example, determined by checking whether a corresponding current flow is caused in reaction to voltages or testing signals, respectively, applied by the testing apparatus 4 to a corresponding device contact (or, respectively, a current flow exceeding a predefined minimal amount), or a corresponding signal (or a signal exceeding a predefined minimal power) is output. In other words, the testing apparatus 4 does not check the—actual—functioning of the device 3a (this will be done later, e.g. at station D), but—merely—the correct contacting between the carrier 11a and the device 3a.

To this end, in an alternative embodiment, one or a plurality of specific contacts may be provided at the device 3a, which are used for performing the contact test method explained (not, however, for the—actual—device functioning tests that are, for instance, performed at station D).

If it is found that (at least with one of the device contacts tested) there is faulty contacting or miscontacting (e.g. since the corresponding feedback signal received by the testing apparatus 4 has too little signal power, or since no feedback signal (at all) is received by the testing apparatus 4 in reaction to a corresponding testing signal), the testing apparatus 4 outputs a corresponding fault signal (FAIL signal) which is, for instance, transferred to the loading machine 10.

Subsequently, the carrier 11a is made to—automatically open again, and the loading or loading-/deloading machine 10, respectively, to take the semiconductor device out of the carrier 11a again (cf. also step IIIb, FIG. 3).

Subsequently—in a first variant—the corresponding semiconductor device 3a can, by means of the loading or loading/deloading machine 10, respectively, again be introduced in the carrier 11a, and the carrier 11 then can again be closed, and—as described above—the above-mentioned contact test can again be carried out.

Alternatively—in a second variant—the semiconductor device 3a taken out of the carrier 11a by the loading or loading-/deloading machine 10, respectively, is (automatically) disposed of or removed, respectively, and another semiconductor device is taken by the loading or loading-/deloading machine 10, respectively, instead and is introduced in the carrier 11a (and then the carrier 11a is closed again and the above-mentioned contact test is performed again, i.e. it is tested whether the other semiconductor device correctly contacts the carrier 11a or not).

In a third, alternative variant the carrier 11a is exchanged instead after the device 3a has been taken out of the carrier 11a by the loading or loading-/deloading machine 10, respectively.

Any combination of the above-mentioned three variants will also be conceivable.

For example, once or several times in succession one and the same device 3a may (again) be introduced in the carrier 11a and a corresponding contact test may be performed.

Subsequently—in case the testing apparatus 4 still outputs a corresponding fault signal (FAIL signal)—it is, possibly, tried one or several times to load the carrier —successfully—with another device (and then—in case a fault signal is still output—with one or a plurality of further devices, etc.).

Next, or alternatively, the carrier 11a may be exchanged.

If the testing apparatus 4 detects that faulty contacting or miscontacting exists with none of the respectively tested device contacts, an OK signal (PASS signal) is output instead of the above-mentioned fault signal (FAIL signal) and is, for example, transferred to the loading or loading-/deloading machine 10 (and/or to another one that is not illustrated here, or to the conveying machine already mentioned above).

The conveying machine (or, alternatively, the loading or loading-/deloading machine 10, respectively) then loads the corresponding carrier 11a—again referring to FIG. 1—together with the semiconductor device 3a that is included therein—again in an automated manner—onto a corresponding conveying means, e.g. a tray 13, by means of which the carrier 11a (and the semiconductor device contained therein) is—together with further carriers lIb, 11c, lId (that contain corresponding semiconductor devices and have been tested appropriately) transported further to the following station 0 (cf. Arrows H and I, as well as step 1lIa, FIG. 3).

Subsequently, at the carrier loading station C, a—new carrier (instead of the carrier 11a) is introduced by means of the above-mentioned, not illustrated, separate machine (or e.g. the above-mentioned loading or loading-/conveying machine, respectively) in the carrier socket 12 or carrier adapter 12, respectively, connected with the testing apparatus 4 (whereupon a new semiconductor device is introduced in the corresponding carrier and the above-mentioned contact test is performed again).

At station D, the corresponding carrier 11a (and the semiconductor device 3a included therein) that has been transported further by the tray 13 is meanwhile introduced, by means of a further, not illustrated, machine to a further carrier socket of a further testing system 15 connected with a further testing apparatus 16, and then the corresponding semiconductor device 3a is subject to a (conventional) device functioning test checking the functioning of the semiconductor device 3a, or to a “burn-in” test, respectively (i.e. a test under extreme conditions (high temperature, etc.) causing quicker ageing of the device 3a).

Additionally, a contact test corresponding to the above-explained contact test performed at the carrier loading station C is performed.

This ensures that the corresponding contacts of the device 3a—still—correctly contact the corresponding contacts of the carrier 11a.

Since—as explained above—a corresponding contact test was, in the embodiment shown here, already performed at the carrier loading station c (cf. also FIG. 3), it can be avoided that carriers 11a having faulty contacting or miscontacting right from the outset are (in vain) transported from the carrier loading station c further to the (actual) test station d.

1 list of reference signs

1 testing system

2 wafer

3a semiconductor device

3b semiconductor device

3c semiconductor device

3d semiconductor device

4 testing apparatus

5 testing system

6 testing apparatus

7 sawing machine

8 probe card

9a contact needle 15

9b contact needle

10 loading machine

11a carrier

11b carrier

11c carrier

11d carrier

12 socket

13 tray

14 lines

15 testing system

16 testing apparatus

What is claimed is:

1. A testing method for testing contacting between a semiconductor device and a carrier, comprising loading the carrier with the semiconductor device, such that contacting between the carrier and the semiconductor device is tested immediately after the loading of the carrier with the semiconductor device.

2. The testing method according to claim 1, further comprising connecting the carrier to a testing apparatus.

3. The testing method according to claim 2, wherein the carrier is connected to the testing apparatus, and the carrier is subsequently loaded with the semiconductor device.

4. The testing method according to claim 1, wherein the carrier is loaded at a carrier loading station, and the contacting between the carrier and the semiconductor device is tested before the carrier is transported to a further station.

5. The testing method according to claim 2, wherein the contacting between the carrier and the semiconductor device is tested by the testing apparatus.

6. The testing method according to claim 5, wherein the testing apparatus is configured such that it tests the contacting between the carrier and the semiconductor device, but not functioning of the semiconductor device.

7. The testing method according to claim 1, wherein the contacting between the carrier and the semiconductor device is tested less than 2 seconds after loading of the carrier with the semiconductor device.

8. The testing method according to claim 1, further comprising determining during the testing of the contacting between the carrier and the semiconductor device whether an electric contact has been established between a corresponding pad of the semiconductor device and an assigned pad of the carrier after loading of the carrier with the semiconductor device.

9. The testing method according to claim 1, further comprising determining during the testing of the contacting between the carrier and the semiconductor device whether a respective electric contact has been established between a plurality of pads of the semiconductor device and respectively assigned pads of the carrier after loading of the carrier with the semiconductor device.

10. The testing method according to claim 8, wherein power of current flowing through the corresponding semiconductor device pad is determined to find whether an electric contact has been established between a corresponding pad of the semiconductor device and an assigned pad of the carrier.

11. The testing method according to claim 8, wherein an amount of voltage dropping across the corresponding semiconductor device pad is determined to find whether an electric contact has been established between a corresponding pad of the semiconductor device and an assigned pad of the carrier.

12. A testing system for testing contacting between a semiconductor device and a carrier, comprising a testing apparatus to which a carrier can be connected, and which is configured such that contacting between the carrier and the semiconductor device is tested by the testing device immediately after loading of the carrier with a semiconductor device.

13. The testing system according to claim 12, wherein the testing apparatus performs the test after a signal is output by a loading device, the signal indicating that the carrier was loaded with the semiconductor device.

14. The testing system according to claim 12, further comprising a testing apparatus, the testing apparatus being configured such that contacting between the carrier and the semiconductor device is tested immediately after loading of the carrier with the semiconductor device.
